(19) United States
(12) Patent Application Publication
(10) Pub. No.: US 2025/0309019 A1
(43) Pub. Date: Oct. 2, 2025

(54) PACKAGED CIRCUIT AND RELATED VEHICLES

(71) Applicant: TEXAS INSTRUMENTS INCORPORATED, Dallas, TX (US)

(72) Inventors: Jane Qian LIU, Plano, TX (US); Ying-Chang CHEN, Hsinchu Hsien (TW); William R. MORRISON, Plano, TX (US)

(21) Appl. No.: 18/620,741

(22) Filed: Mar. 28, 2024

(51) Int. Cl. H01L 23/31; H01L 21/56; H01L 23/00; H01L 23/10; H01L 23/498

(52) U.S. Cl. CPC H01L 23/3192; H01L 21/56; H01L 23/10; H01L 23/49838; H01L 24/29; H01L 24/32; H01L 24/48; H01L 24/73; H01L 24/92; H01L 2224/26175; H01L 2224/32225; H01L 2224/48227; H01L 2224/73215; H01L 2224/92165

(57) ABSTRACT

An apparatus includes: a substrate having a first set of bond pads; an integrated circuit (IC) having a second set of bond pads; bond wires between bond pads of the first set of bond pads and respective bond pads of the second set of bond pads; a first encapsulant layer in contact with the substrate and spaced away from the IC; a second encapsulant layer in contact with the IC and spaced away from the substrate, the second encapsulant layer separated from the first encapsulant layer by a gap; and a third encapsulant layer in contact with at least one of the first encapsulant layer and the second encapsulant layer, the third encapsulant layer at least partially covering the gap.

### CROSS REFERENCE TO RELATED APPLICATION

The present application claims priority to U.S. Provisional Application No. 63/599,334, titled “MULTILAYER EPROXY GEL PROCESS FOR LOW STRESS PACKAGE INTEGRATION”, Attorney Docket number T104120US01, filed on Nov. 15, 2023, which is hereby incorporated by reference in its entirety.

### BACKGROUND

Packaged circuits, such as integrated circuits (ICs), are subject to package stress. One of the causes of package stress is contact between packaged circuit materials having different coefficients of thermal expansion (CTEs). Due to such package stress, some packaged circuits are unable to pass reliability testing, such as Q100 reliability testing (−55° C. to 125° C.), which limits circuit applications. For example, a packaged circuit that does not pass Q100 reliability testing may be unsuitable for use in a vehicle.

### SUMMARY

In an example, a system comprises: an apparatus includes: a substrate having a first set of bond pads; an integrated circuit (IC) having a second set of bond pads; bond wires between bond pads of the first set of bond pads and respective bond pads of the second set of bond pads; a first encapsulant layer in contact with the substrate and spaced away from the IC; a second encapsulant layer in contact with the IC and spaced away from the substrate, the second encapsulant layer separated from the first encapsulant layer by a gap; and a third encapsulant layer in contact with at least one of the first encapsulant layer and the second encapsulant layer, the third encapsulant layer at least partially covering the gap.

In another example, a vehicle includes: an electronic control unit (ECU); and projection circuitry coupled to the ECU. The projection circuitry includes a spatial light modulator (SLM). The SLM includes: a substrate having a first set of bond pads; an IC having a second set of bond pads; bond wires between bond pads of the first set of bond pads and respective bond pads of the second set of bond pads; a first encapsulant layer in contact with the substrate and spaced away from the IC; a second encapsulant layer in contact with the IC and spaced away from the substrate, the second encapsulant layer separated from the first encapsulant layer by a gap; and a third encapsulant layer in contact with at least one the first encapsulant layer and the second encapsulant layer, the third encapsulant layer at least partially covering the gap.

In yet another example, a method includes: obtaining a substrate and an IC; applying a first encapsulant layer, the first encapsulant layer contacting the substrate and not the IC; applying a second encapsulant layer, the second encapsulant layer contacting the IC and not the substrate, and the second encapsulant layer separated from the first encapsulant layer by a gap; partially curing the first encapsulant layer and the second encapsulant layer; applying a third encapsulant layer after partially curing the first encapsulant layer and the second encapsulant layer, the third encapsulant layer contacting at least one of the first encapsulant layer and the second encapsulant layer, the third encapsulant layer at least partially covering the gap; and curing the first encapsulant layer, the second encapsulant layer, and the third encapsulant layer.

### BRIEF DESCRIPTION OF THE DRAWINGS

FIG. 1 is a diagram of a vehicle in accordance with various examples.

FIG. 2A is a cross-sectional view of packaged circuit components in accordance with various examples.

FIG. 2B is a perspective view of the packaged circuit components of FIG. 2A in accordance with various examples.

FIG. 3A is a cross-sectional view of packaged circuit components in accordance with various examples.

FIG. 3B is a topside view of the packaged circuit components of FIG. 3A in accordance with various examples.

FIGS. 4 to 12 are cross-sectional views of packaged circuit components, including encapsulant layers, in accordance with various examples.

FIG. 13 is a graph of specific strain energy for different packaged circuit designs and temperatures.

FIG. 14 is a method in accordance with various examples.

FIGS. 15A to 15G are cross-sectional views related to the method of FIG. 6 in accordance with various examples.

### DETAILED DESCRIPTION

The same reference numbers or other reference designators are used in the drawings to designate the same or similar features. Such features may be the same or similar either by function and/or structure.

Described herein are techniques to manufacture low-stress packaged circuits. Each packaged circuit may be a semiconductor-based integrated circuit (IC), a microelectromechanical system (MEMS) device, and/or other packaged circuit. The described low-stress packaged circuits are able to pass reliability testing, such as Q100 reliability testing (−55° C. to 125° C.) and are suitable for a vehicle and/or other environment. In some examples, manufacturing a low-stress packaged circuit includes: applying encapsulant layers to target areas, where the encapsulant layers are spaced away from each other; and partially curing the spaced encapsulant layers. In some examples, additional encapsulant layers may be used to cover a gap between the partially cured and spaced encapsulant layers. The additional encapsulant layers may then be partially cured. After partially cured encapsulant layers cover the target areas and related gaps are covered and possibly partially cured, all encapsulant layers may be cured and additionally baked.

In some examples, the described low-stress packaged circuits reduce stress to packaged circuit materials and reduce silicon cracks, glass cracks, wire lifting at ball bonds, and/or broken wires due to thermal stress. The described low-stress packaged circuits also reduce peel stress of the encapsulant material on all surfaces contacted. In some examples, manufacturing low-stress packaged circuits involves application of and partial curing of gel epoxies with a coefficient of thermal expansion (CTE) below 25. In some examples, the described manufacturing process does not add additional cost, does not reduce production throughput, and may be performed with available equipment. In some examples, the described manufacturing process creates multiple gel epoxy layers for dimension control without cross link reactions in the gel epoxy layers.

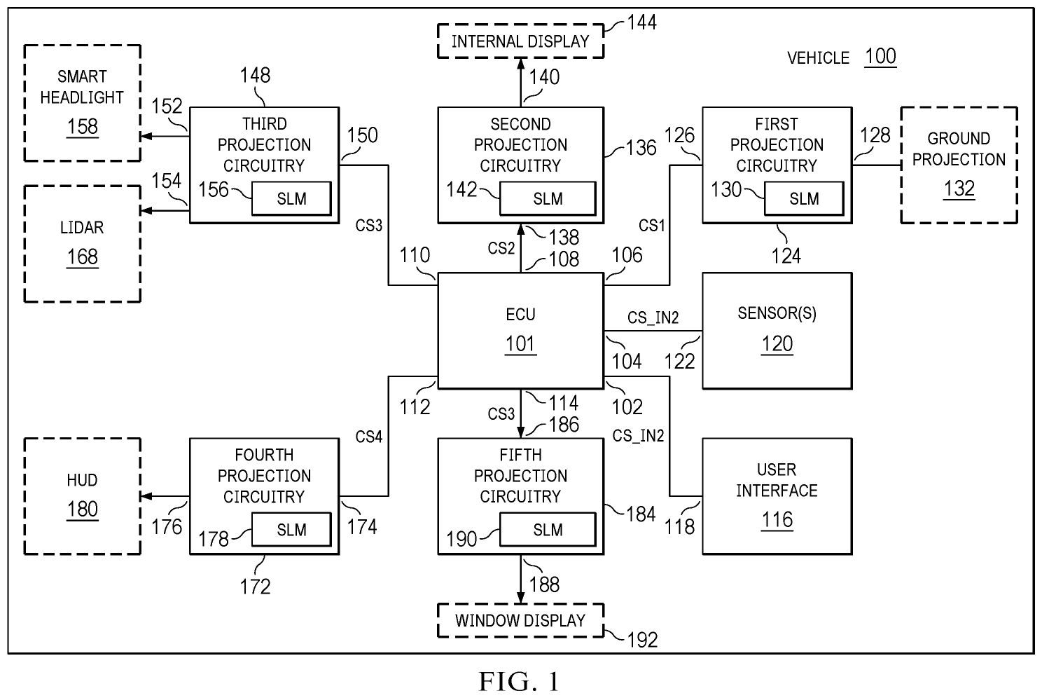

FIG. 1 is a diagram of a vehicle 100 in accordance with various examples. The vehicle 100 may be a land-based vehicle (e.g., a car or truck), a water-based vehicle (e.g., a boat), or an air-based vehicle (e.g., an airplane). As shown, the vehicle 100 includes an electronic control unit (ECU) 101, first projection circuitry 124, second projection circuitry 136, third projection circuitry 148, fourth projection circuitry 172, fifth projection circuitry 184, sensor(s) 120, and a user interface 116. The ECU 101 has a first terminal 102, a second terminal 104, a third terminal 106, a fourth terminal 108, a fifth terminal 110, a sixth terminal 112, and a seventh terminal 114. The sensor(s) 120 has a terminal 122. The user interface 116 has a terminal 118.

In the example of FIG. 1, the first projection circuitry 124 has a terminal 126 and an optical output 128. The first projection circuitry 124 includes a first spatial light modulator (SLM) 130. The second projection circuitry 136 has a terminal 138 and an optical output 140. The second projection circuitry 136 includes a second SLM 142. The third projection circuitry 148 has a terminal 150, a first optical output 152, and a second optical output 154. The third projection circuitry 148 includes a third SLM 156. The fourth projection circuitry 172 has a terminal 174 and an optical output 176. The fourth projection circuitry 172 includes a fourth SLM 178. The fifth projection circuitry 184 has a terminal 186 and an optical output 188. The fifth projection circuitry 184 includes a fifth SLM 190.

In the example of FIG. 1, the first terminal 102 of the ECU 101 is coupled to the terminal 118 of the user interface 116. The second terminal 104 of the ECU 101 is coupled to the terminal 122 of the sensor(s) 120. The third terminal 106 of the ECU 101 is coupled to the terminal 126 of the first projection circuitry 124. The fourth terminal 108 of the ECU 101 is coupled to the terminal 138 of the second projection circuitry 136. The fifth terminal 110 of the ECU 101 is coupled to the terminal 150 of the third projection circuitry 148. The sixth terminal 112 of the ECU 101 is coupled to the terminal 174 of the fourth projection circuitry 172. The seventh terminal 114 of the ECU 101 is coupled to the terminal 186 of the fifth projection circuitry 184.

In some examples, the ECU 101 is configured to: receive first input control signals (CS_IN1) from the user interface 116 at the first terminal 102; receive second input control signals (CS_IN2) from the sensor(s) 120 at the second terminal 104; provide first control signals (CS1) at the third terminal 106 responsive to CS_IN1, CS_IN2, and/or ground projection control operations of the ECU 101; provide second control signals (CS2) at the fourth terminal 108 responsive to CS_IN1, CS_IN2, and/or internal display control operations of the ECU 101; provide third control signals (CS3) at the fifth terminal 110 responsive to CS_IN1, CS_IN2, smart headlight control operations of the ECU 101, and/or light detection and ranging (LIDAR) control operations of the ECU 101; provide fourth control signals (CS4) at the sixth terminal 112 responsive to CS_IN1, CS_IN2, and/or head-up display control operations of the ECU 101; provide fifth control signals (CS5) at the seventh terminal 114 responsive to CS_IN1, CS_IN2, and/or window display control operations of the ECU 101.

In some examples, the first projection circuitry 124 operates to provide a ground projection 132 via the optical output 128 responsive to CS1 and operations of the first SLM 130. The second projection circuitry 136 operates to provide an internal display projection 144 via the optical output 140 responsive to CS2 and operations of the second SLM 142. The third projection circuitry 148 operates to provide a smart headlight projection 158 via the first optical output 152 and/or a LIDAR projection 168 via the second optical output 154 responsive to CS3 and operations of the third SLM 156. The fourth projection circuitry 172 operates to provide a HUD projection 180 via the optical output 176 responsive to CS4 and operations of the fourth SLM 178. The fifth projection circuitry 184 operates to provide a window display projection 192 via the optical output 188 responsive to CS5 and operations of the fifth SLM 190.

In some examples, the first projection circuitry 124, the second projection circuitry 136, the third projection circuitry 148, the fourth projection circuitry 172, and the fifth projection circuitry 184 support different projection resolutions and/or brightness levels. In different examples, the vehicle 100 may omit one or more of the first projection circuitry 124, the second projection circuitry 136, the third projection circuitry 148, the fourth projection circuitry 172, and the fifth projection circuitry 184. In some examples, different projections options may be supported by a single projection circuit. For example, the third projection circuitry 148 of FIG. 1 supports a smart headlight projection 158 and a LIDAR projection 168. In other examples, the smart headlight projection 158 and the LIDAR projection 168 may be supported by different projection circuitry. Also, it may be possible to support other combinations of projections with one projection circuitry. In different examples, the first SLM 130, the second SLM 142, the third SLM 156, the fourth SLM 178, and the fifth SLM 190 may support the same projection resolution or different projection resolutions.

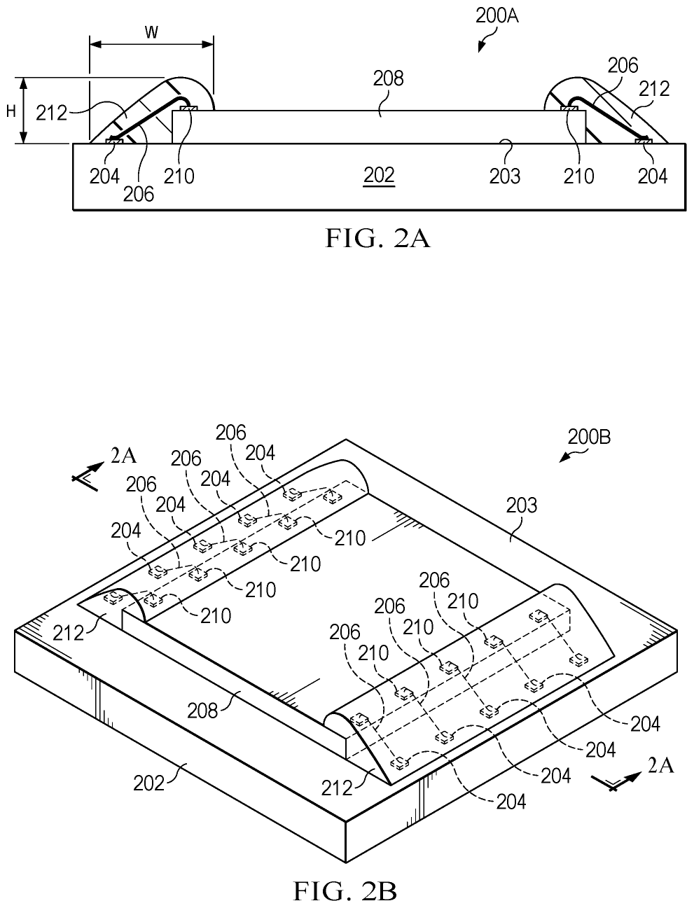

FIG. 2A is a cross-sectional view 200A of packaged circuit components in accordance with various examples. The cross-sectional view 200A relates to the cross-sectional plane “2A” in the perspective view 200B of FIG. 2B. In the example of FIG. 2A, the packaged circuit components include: a substrate 202 having a primary surface 203 and first bond pads 204; an IC 208 having second bond pads 210; bond wires 206 that electrically couple first bond pads 204 to respective bond pads of the second bond pads 210; and an encapsulant 212. As shown, the first bond pads 204 are on the primary surface 203 of the substrate 202. Without limitation, the substrate 202 may be a ceramic material.

In the example of FIG. 2A, packaging of the packaged circuit components includes attaching the IC 208 to the primary surface 203 of the substrate 202 using an adhesive or other bonding option. The bond wires 206 are then soldered or otherwise electrically coupled to respective bond pads of the first bond pads 204 and to respective bond pads of the second bond pads 210. After the bond wires 206 have been added, the encapsulant 212 is added to cover the first bond pads 204, the second bond pads 210, and the bond wires 206. In different examples, multiple sides (e.g., 2 sides, 3 sides, or 4 sides) of the IC 208 and the substrate 202 may include respective bond pads, respective bond wires, and a respective encapsulant.

In some examples, the encapsulant 212 is formed using: a first encapsulant layer in contact with the substrate 202 and spaced away from the IC 208; a second encapsulant layer in contact with the IC 208 and spaced away from the substrate 202, the second encapsulant layer separated from the first encapsulant layer by a gap; and a third encapsulant layer in contact with at least one of the first encapsulant layer and the second encapsulant layer, the third encapsulant layer at least partially covering the gap. By strategic application of different encapsulant layers and partial curing of at least some of the different encapsulant layers of the encapsulant 212, the packaged circuit components are able to pass reliability testing, such as Q100 reliability testing (−55° C. to 125° C.) and are suitable for a vehicle and/or other environment. In some examples, the first encapsulant layer, the second encapsulant layer, and the third encapsulant layer form a combined encapsulant over a first set of bond pads, a second set of bond pads, and respective bond wires. In some examples, the combined encapsulant has a width (labeled “W” in FIG. 2A) between 0.5 mm to 4 mm and has a height (labeled “H” in FIG. 2A) between 0.5 mm to 5 mm. In some examples, the first encapsulant layer, the second encapsulant layer, and the third encapsulant layer are made from epoxy gel having a coefficient of thermal expansion (CTE) below 25.

FIG. 2B is a perspective view 200B of the packaged circuit components of FIG. 2A in accordance with various examples. As shown in FIG. 2B, the first bond pads 204 of the substrate 202 are visible as part of a first set of bond pads of the substrate 202. Also, the second bond pads 210 of the IC 208 are visible as part of a second set of bond pads of the IC 208. The bond wires 206 are visible as part of a set of bond wires. As shown, respective bond pads 204 of the first set of bond pads of the substrate 202 are electrically coupled to respective bond pads 210 of the second set of bond pads of the IC 208. In the perspective view 200B, the encapsulant 212 is visible as covering the first set of bond pads of the substrate 202, the second set of bond pads of the IC 208, and the set of bond wires. In different examples, multiple sides (e.g., 2 sides, 3 sides, or 4 sides) of the IC 208 and the substrate 202 may include respective bond pads, respective bond wires, and respective encapsulants.

In the example of FIG. 2B, packaging of the packaged circuit components includes attaching the IC 208 to the primary surface 203 of the substrate 202 using an adhesive or other bonding option. Bond wires are then soldered or otherwise electrically coupled to respective bond pads. After bond wires have been added, encapsulants are formed to cover respective bond pads of the substrate 202, respective bond pads of the IC 208, and respective bond wires.

In some examples, each encapsulant is formed using: a first encapsulant layer in contact with the substrate 202 and spaced away from the IC 208; a second encapsulant layer in contact with the IC 208 and spaced away from the substrate 202, the second encapsulant layer separated from the first encapsulant layer by a gap; and a third encapsulant layer in contact with at least one of the first encapsulant layer and the second encapsulant layer, the third encapsulant layer at least partially covering the gap. By more careful application of different encapsulant layers and partial curing of at least some of the different encapsulant layers of each encapsulant, the packaged circuit components are able to pass reliability testing, such as Q100 reliability testing (−55° C. to 125° C.) and are suitable for a vehicle and/or other environment. In some examples, the first encapsulant layer, the second encapsulant layer, and the third encapsulant layer form a combined encapsulant over the first set of bond wires, the second set of bond wires, and the bond wires. In some examples, the combined encapsulant has a width between 0.5 mm to 4 mm and has a height between 0.5 mm to 5 mm. In some examples, the first encapsulant layer, the second encapsulant layer, and the third encapsulant layer are made from epoxy gel having a CTE below 25.

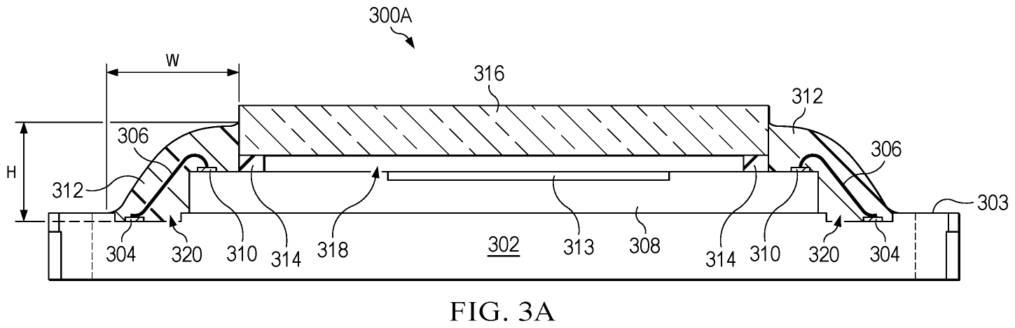

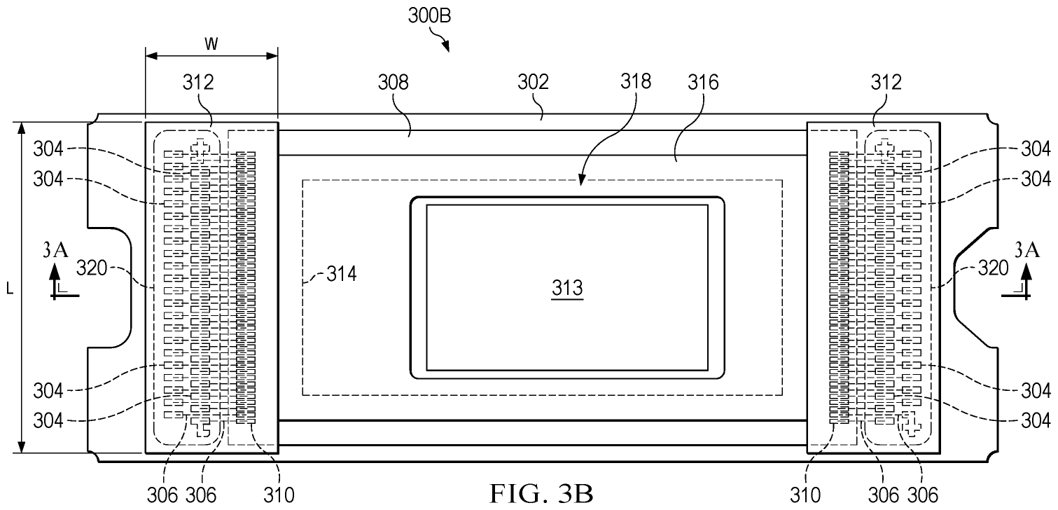

FIG. 3A is another cross-sectional view 300A of the packaged circuit components in accordance with various examples. The cross-sectional view 300A relates to the cross-sectional plane “3A” in the top view 300B of FIG. 3B. The packaged circuit components include: a substrate 302 having a primary surface 303 and a bond pad well 320 that includes first bond pads 304; an IC 308 having second bond pads 310; bond wires 306; encapsulants 312; a cap 316 (e.g., a transparent material, such as glass, or a non-transparent material, such as a semiconductor material); circuitry 313; and seals 314. In some examples, the circuitry 313 includes spatial light modulator components including control circuitry. In some examples, such spatial light modulator components are part of a digital micromirror device (DMD). In other examples, the circuitry 313 includes micro-electromechanical system (MEMS) components, sense circuitry, control circuitry for MEMS components, display control circuitry, projector control circuitry, and/or control circuitry responsive to sense parameters detected by sense circuitry. In the example of FIG. 3A, a sealed chamber 318 is formed by the IC 308, the cap 316, and the seals 314. In an example, the sealed chamber 318 is hermetically sealed. In an example, the seals 314 includes metal layers and/or an interposer. Without limitation, the substrate 302 may be a ceramic material.

In the example of FIG. 3A, packaging of the packaged circuit components includes attaching the IC 308 to the primary surface 303 of the substrate 302 using an adhesive or other bonding option. The cap 316 is then attached via the seals 314. The bond wires 306 are then soldered or otherwise electrically coupled to respective bond pads of the first bond pads 304 and respective bond pads of the second bond pads 310. After the bond wires 306 have been added, the encapsulants 312 are added to cover the first bond pads 304, the second bond pads 310, and the bond wires 306. In different examples, multiple sides (e.g., 2 sides, 3 sides, or 4 sides) of the IC 308 and the substrate 302 may include respective bond pads, respective bond wires, and respective encapsulants.

In some examples, each of the encapsulants 312 is formed using: a first encapsulant layer in contact with the substrate 302 and spaced away from the IC 308; a second encapsulant layer in contact with the IC 308 and spaced away from the substrate 302, the second encapsulant layer separated from the first encapsulant layer by a gap; and a third encapsulant layer in contact with at least one of the first encapsulant layer and the second encapsulant layer, the third encapsulant layer at least partially covering the gap. By strategic application of different encapsulant layers and partial curing of at least some of the different encapsulant layers of each of the encapsulants 312, the packaged circuit components are able to pass reliability testing, such as Q100 reliability testing (−55° C. to 125° C.) and are suitable for a vehicle and/or other environment. In some examples, the first encapsulant layer, the second encapsulant layer, and the third encapsulant layer form a combined encapsulant over the first set of bond wires, the second set of bond wires, and the bond wires. In some examples, the combined encapsulant has a width (“W” in FIG. 3A) between 0.5 mm to 4 mm and has a height (“H” in FIG. 3A) between 0.5 mm to 5 mm. In some examples, the first encapsulant layer, the second encapsulant layer, and the third encapsulant layer are made from epoxy gel having a CTE below 25.

FIG. 3B is a top view 300B of the packaged circuit components of FIG. 3A in accordance with various examples. In the top view 300B, the first bond pads 304 of the substrate 302 are visible as part of a first set of bond pads of the substrate 302. Also, the second bond pads 310 of the IC 308 are visible as part of a second set of bond pads of the IC 308. The bond wires 306 are visible as part of a set of bond wires. As shown, respective bond pads of the first set of bond pads of the substrate 302 are electrically coupled to respective bond pads of the second set of bond pads of the IC 308. In the top view 300B, the outline of the encapsulant 312 are visible. Each of the encapsulants 312 cover a respective set of bond pads of the substrate 302, a respective set of bond pads of the IC 308, a respective set of bond wires, and a respective bond well 320. Also, the outlines of the cap 316; the circuitry 313; and the seals 314 are visible in the top view 300B. In different examples, multiple sides (e.g., 2 sides, 3 sides, or 4 sides) of the IC 308 and the substrate 302 may include respective bond pads, respective bond wires, and respective encapsulants.

In the example of FIG. 3B, packaging of the packaged circuit components includes attaching the IC 308 to the primary surface 303 of the substrate 302 using an adhesive or other bonding option. The bond wires 306 are then soldered or otherwise electrically coupled to respective bond pads of the first bond pads 304 and respective bond pads of the second bond pads 310. After bond wires 306 have been added, the encapsulants 312 are formed to cover respective bond pads of the substrate 302, respective bond pads of the IC 308, and respective bond wires.

In some examples, each of the encapsulants 312 is formed using: a first encapsulant layer in contact with the substrate 302 and spaced away from the IC 308; a second encapsulant layer in contact with the IC 308 and spaced away from the substrate 302, the second encapsulant layer separated from the first encapsulant layer by a gap; and a third encapsulant layer in contact with at least one of the first encapsulant layer and the second encapsulant layer, the third encapsulant layer at least partially covering the gap. By strategic application of different encapsulant layers and partial curing of at least some of the different encapsulant layers of each encapsulant, the packaged circuit components are able to pass reliability testing, such as Q100 reliability testing (−55° C. to 125° C.) and are suitable for a vehicle and/or other environment. In some examples, the first encapsulant layer, the second encapsulant layer, and the third encapsulant layer form a combined encapsulant over the first set of bond wires, the second set of bond wires, and the bond wires. In some examples, the combined encapsulant has a width between 0.5 mm to 4 mm and has a height between 0.5 mm to 5 mm. In some examples, the first encapsulant layer, the second encapsulant layer, and the third encapsulant layer are made from epoxy gel having a CTE below 25.

In some examples, package dimensions for the components in FIGS. 3A and 3B may be 4 mm to 25 mm in a width (“W”) direction, 10 mm to 50 mm in a length (“L”) direction, and 0.5 mm to 6 mm in a height (“H”) direction. In some examples, each of the encapsulants 312 may be 0.5 mm to 4 mm in the W direction, at least the size of the IC 308 in the L direction, and 0.5 mm to 6 mm in the H direction.

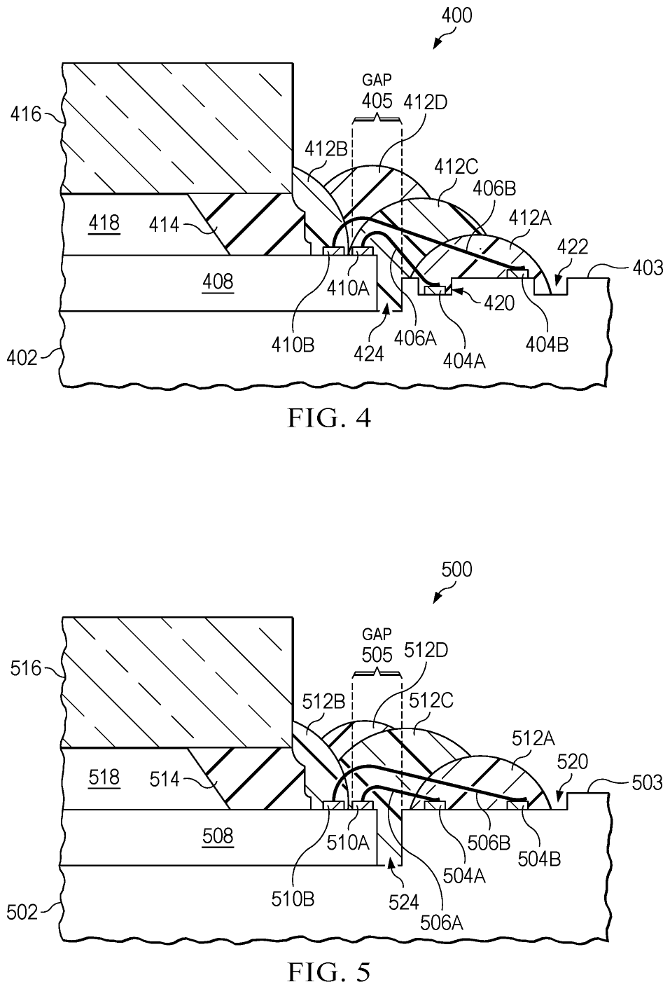

FIGS. 4 to 12 are cross-sectional views 400, 500, 600, 700, 800, 900, 1000, 1100, and 1200 of packaged circuit components, including encapsulant layers, in accordance with various examples. In the example of FIG. 4, the packaged circuit components in the cross-sectional view 400 include: a substrate 402 with primary surface 403 and a cavity 424 relative to the primary surface 403; an IC 408; seals 414; a cap 416 (e.g., a transparent material, such as glass, or a non-transparent material, such as a semiconductor material); bond pads 404A of the substrate 402; bond pads 404B of the substrate 402; bond pads 410A of the IC 408; bond pads 410B of the IC 408; bond wires 406A; bond wires 406B; a bond pad well 420; and an encapsulant control well 422. In the example of FIG. 4, the IC 408, the seals 414, and the cap 416 form a sealed chamber 418. Also, the bond pads 404A are in the bond pad well 420 of substrate 202B, while the bond pads 404B are on the primary surface 403 of the substrate 402.

In the example of FIG. 4, the packaged circuit components include a first encapsulant layer 412A, a second encapsulant layer 412B, a third encapsulant layer 412C, and a fourth encapsulant layer 412D. The first encapsulant layer 412A is in contact with the substrate 402 and is spaced away from the IC 408. Also, the position of the first encapsulant layer 412A is limited by the encapsulant control well 422 (i.e., the first encapsulant layer 412A does not extend axially beyond the encapsulant control well 422). The second encapsulant layer 412B is in contact with the IC 308 and is spaced away from the substrate 402, resulting in a gap 405 between the first encapsulant layer 412A and the second encapsulant layer 412B. In some examples, the second encapsulant layer 412B is also in contact with the cap 416. In the example of FIG. 4, the third encapsulant layer 412C and/or the fourth encapsulant layer 412D cover the gap 405 between the first encapsulant layer 412A and the second encapsulant layer 412B.

In different examples, the size of the gap 405 may vary depending on: the spacing between bond pads of the IC 408 (e.g., the bond pads 410A and/or the bond pads 410B in FIG. 4) and bond pads of the substrate 402 (e.g., the bonds pads 404A and/or the bond pads 404B); the position of the seals 414 relative to bonds pads of the IC 408 (e.g., the bond pads 410A and/or the bond pads 410B in FIG. 4), the outer edge of the IC 408, or the dimensions of the cavity 424; the position of the cap 416 relative to the bond pads of the IC 408 (e.g., the bond pads 410A and/or the bond pads 410B in FIG. 4), the outer edge of the IC 408, or the dimensions of the cavity 424. In some examples, the size of the gap 405 is determined, at least in part, by the volume of encapsulant dispensed for each encapsulant layer during encapsulation operations. The volume of encapsulant dispensed for each encapsulant layer may vary, for example, based on available dispensing technology and cost considerations. In the example of FIG. 4, the first encapsulant layer 412A covers the bonds pads 404A and 404B of the substrate 402 and part of the bond wires 406A and 406B, the second encapsulant layer 412B covers the bonds pads 410B of the IC 408 and part of the bond wires 406B, the third encapsulant layer 412C covers most of the gap 405, part of the bond wires 406A and 406B, and the bond pads 410A of the IC 408, and the fourth encapsulant layer 412D covers remaining portion of the gap 405, part of the bond wires 406B, part of the second encapsulant layer 412B, and part of the third encapsulant layer 412C. In different examples, the number, the size, and the position of encapsulant layers may vary.

In some examples, the first encapsulant layer 412A and the second encapsulant layer 412B are applied before the third encapsulant layer 412C and the fourth encapsulant layer 412D. In such examples, the first encapsulant layer 412A and the second encapsulant layer 412B may be partially cured before the third encapsulant layer 412C and the fourth encapsulant layer 412D are applied. After application, the third encapsulant layer 412C and the fourth encapsulant layer 412D may also be partially cured. After being partial cured, the first encapsulant layer 412A, the second encapsulant layer 412B, the third encapsulant layer 412C, and the fourth encapsulant layer 412C are cured.

In the example of FIG. 4, the IC 408 is positioned in the cavity 424, which reduces the offset between the top of the IC 408 and the primary surface 403 of the substrate 302. By placing the IC 408 in the cavity 424, the length of bond wires (e.g., the bond wires 406A and the bond wires 406B), the amount of encapsulant, and the total height of the packaged circuit components may be reduced.

FIG. 5 is a cross-sectional view 500 of packaged circuit components, including encapsulant layers, in accordance with various examples. In the example of FIG. 5, the packaged circuit components in the cross-sectional view 500 include: a substrate 502 with primary surface 503 and a cavity 524 relative to the primary surface 503; an IC 508; seals 514; a cap 516 (e.g., a transparent material, such as glass, or a non-transparent material, such as a semiconductor material); bond pads 510A of the IC 508; bond pads 510B of the IC 508; bond pads 504A of the substrate 502; bond pads 504B of the substrate 502; bond wires 506A; bond wires 506B; and a bond pad shelf 520. In the example of FIG. 4, the IC 508, the seals 514, and the cap 516 form a sealed chamber 518.

In the example of FIG. 5, the bond pads 504A and the bond pads 504B are on the bond pad shelf 520 of the substrate 502. In the example of FIG. 5, the bond pad shelf 520 is offset from the primary surface 503 and the cavity 524. In the example of FIG. 5, the bond pad shelf 520 is aligned with the top of the IC 508, which reduces bond wire length and encapsulant volume. In other examples, the bond pad shelf 520 may be offset (above or below) from the top of the IC 508.

In the example of FIG. 5, the packaged circuit components include a first encapsulant layer 512A, a second encapsulant layer 512B, a third encapsulant layer 512C, and a fourth encapsulant layer 512D. The first encapsulant layer 512A is in contact with the substrate 502 and is spaced away from the IC 508. Also, the position of the first encapsulant layer 512A may be limited by the bond pad shelf 520 (i.e., the first encapsulant layer 512A does not extend axially beyond the bond pad shelf 520). The second encapsulant layer 512B is in contact with the IC 508 and is spaced away from the substrate 502, resulting in a gap 505 between the first encapsulant layer 512A and the second encapsulant layer 512B. In some examples, the second encapsulant layer 512B is also in contact with the cap 516. In the example of FIG. 5, the third encapsulant layer 512C and/or the fourth encapsulant layer 512D may cover the gap 505 between the first encapsulant layer 512A and the second encapsulant layer 512B. In some examples, the fourth encapsulant layer 512D may be omitted.

In different examples, the size of the gap 505 may vary depending on: the spacing between bond pads of the IC 508 (e.g., the bond pads 510A and/or the bond pads 510B in FIG. 5) and bond pads of the substrate 502 (e.g., the bonds pads 504A and/or the bond pads 504B); the position of the seals 514 relative to bonds pads of the IC 508 (e.g., the bond pads 510A and/or the bond pads 510B in FIG. 5), the outer edge of the IC 508, or the dimensions of the cavity 524; the position of the cap 516 relative to the bond pads of the IC 508 (e.g., the bond pads 510A and/or the bond pads 510B in FIG. 5), the outer edge of the IC 508, or the dimensions of the cavity 524. In some examples, the size of the gap 505 is determined, at least in part, by the volume of encapsulant dispensed for each encapsulant layer during encapsulation operations. The volume of encapsulant dispensed for each encapsulant layer may vary, for example, based on available dispensing technology and cost considerations. In the example of FIG. 5, the first encapsulant layer 512A covers the bonds pads 504A and 504B of the substrate 502 and part of the bond wires 506A and 506B, the second encapsulant layer 512B covers the bonds pads 510B of the IC 508 and part of the bond wires 506B, the third encapsulant layer 512C covers the gap 505, part of the bond wires 506A and 506B, and the bond pads 510A of the IC 508, and the fourth encapsulant layer 512D covers part of the second encapsulant layer 512B and part of the third encapsulant layer 512C. In different examples, the number, the volume, and the position of encapsulant layers may vary.

In some examples, the first encapsulant layer 512A and the second encapsulant layer 512B are applied before the third encapsulant layer 512C and the fourth encapsulant layer 512D. In such examples, the first encapsulant layer 512A and the second encapsulant layer 512B may be partially cured before the third encapsulant layer 512C and the fourth encapsulant layer 512D are applied. After application, the third encapsulant layer 512C and the fourth encapsulant layer 512D may also be partially cured. After being partially cured, the first encapsulant layer 512A, the second encapsulant layer 512B, the third encapsulant layer 512C, and the fourth encapsulant layer 512D are cured.

In the example of FIG. 5, the IC 508 is positioned in the cavity 524, which reduces the offset between the top of the IC 508 and the bond pad shelf 520 of the substrate 502. By placing the IC 508 in the cavity 524, the length of bond wires (e.g., the bond wires 506A and the bond wires 506B), the amount of encapsulant, and the total height of the packaged circuit components may be reduced.

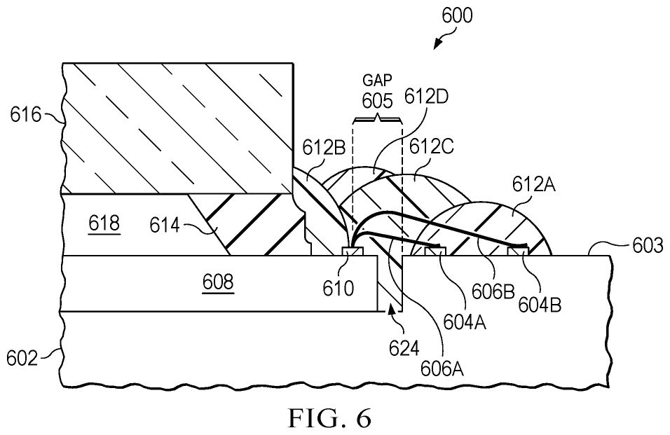

FIG. 6 is a cross-sectional view 600 of packaged circuit components, including encapsulant layers, in accordance with various examples. In the example of FIG. 6, the packaged circuit components in the cross-sectional view 600 include: a substrate 602 with primary surface 603 and a cavity 624 relative to the primary surface 603; an IC 608; seals 614; a cap 616 (e.g., a transparent material, such as glass, or a non-transparent material, such as a semiconductor material); bond pads 610 of the IC 608; bond pads 604A of the substrate 602; bond pads 604B of the substrate 602; bond wires 606A; and bond wires 606B.

In the example of FIG. 6, the IC 608, the seals 614, and the cap 616 form a sealed chamber 618. Also, the bond pads 604A and the bond pads 604B are on the primary surface 603 of the substrate 602 (i.e., a bond pad shelf and an encapsulant control well are not used in FIG. 6). In the example of FIG. 6, the IC 608 is attached to the substrate 602 within the cavity 624 such that the top of the IC 608 is aligned with the primary surface 603 of the substrate 602. In other examples, the top of the IC 608 may be offset (above or below) the primary surface 603 of the substrate 602.

In the example of FIG. 6, the packaged circuit components include a first encapsulant layer 612A, a second encapsulant layer 612B, a third encapsulant layer 612C, and a fourth encapsulant layer 612D. The first encapsulant layer 612A is in contact with the substrate 602 and is spaced away from the IC 608. The second encapsulant layer 612B is in contact with the IC 608 and is spaced away from the substrate 602, resulting in a gap 605 between the first encapsulant layer 612A and the second encapsulant layer 612B. In some examples, the second encapsulant layer 612B is also in contact with the cap 616. In the example of FIG. 6, the third encapsulant layer 612C and/or the fourth encapsulant layer 612D cover the gap 605 between the first encapsulant layer 612A and the second encapsulant layer 612B. In some examples, the fourth encapsulant layer 612D may be omitted.

In different examples, the size of the gap 605 may vary depending on: the spacing between bond pads of the IC 608 (e.g., the bond pads 610A and/or the bond pads 610B in FIG. 6) and bond pads of the substrate 602 (e.g., the bonds pads 504A and/or the bond pads 504B); the position of the seals 514 relative to bonds pads of the IC 508 (e.g., the bond pads 610 in FIG. 6), the outer edge of the IC 608, or the dimensions of the cavity 624; the position of the cap 616 relative to the bond pads of the IC 608 (e.g., the bond pads 610 in FIG. 6), the outer edge of the IC 608, or the dimensions of the cavity 624. In some examples, the size of the gap 605 is determined, at least in part, by the volume of encapsulant dispensed for each encapsulant layer during encapsulation operations. The volume of encapsulant dispensed for each encapsulant layer may vary, for example, based on available dispensing technology and cost considerations. In the example of FIG. 6, the first encapsulant layer 612A covers the bonds pads 604A and 604B of the substrate 602 and part of the bond wires 606A and 606B, the second encapsulant layer 612B covers part of the bonds pads 610 of the IC 608, the third encapsulant layer 512C covers the gap 505, part of the bonds pads 610 of the IC 608, part of the bond wires 606A and 606B, and the fourth encapsulant layer 512D covers part of the second encapsulant layer 612B and part of the third encapsulant layer 612C. In different examples, the number, the volume, and the position of encapsulant layers may vary.

In some examples, the first encapsulant layer 612A and the second encapsulant layer 612B are applied before the third encapsulant layer 612C and the fourth encapsulant layer 612D. In such examples, the first encapsulant layer 612A and the second encapsulant layer 612B may be partially cured before the third encapsulant layer 612C and the fourth encapsulant layer 612D are applied. After application, the third encapsulant layer 612C and the fourth encapsulant layer 612D may also be partially cured. After being partially cured, the first encapsulant layer 612A, the second encapsulant layer 612B, the third encapsulant layer 612C, and the fourth encapsulant layer 612D are cured.

In the example of FIG. 6, the IC 608 is positioned in the cavity 624, which reduces the offset between the top of the IC 608 and the primary surface 603 of the substrate 602. By placing the IC 608 in the cavity 624, the length of bond wires (e.g., the bond wires 606A and the bond wires 606B), the amount of encapsulant, and the total height of the packaged circuit components may be reduced.

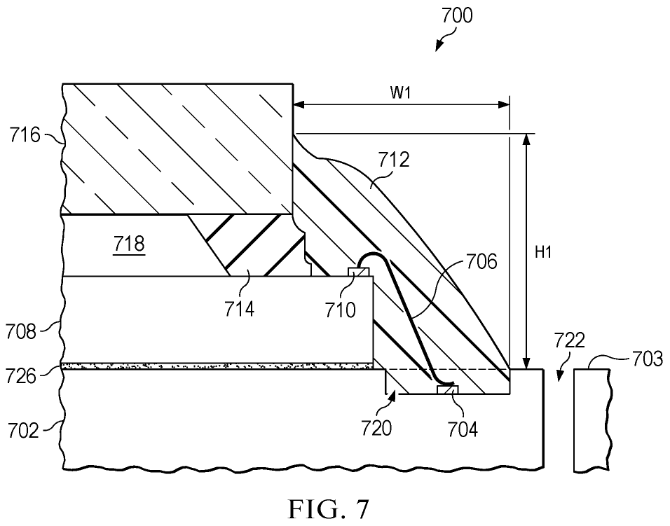

In the example of FIG. 7, the packaged circuit components in the cross-sectional view 700 include: a substrate 702 with a primary surface 703, a bond pad well 720, an encapsulant control well 722; an IC 708; seals 714; a cap 716 (e.g., a transparent material, such as glass, or a non-transparent material, such as a semiconductor material); bond pads 710 of the IC 708; bond pads 704 of the substrate 702; bond wires 706; and an encapsulant 712. In the example of FIG. 7, the encapsulant 712 has width W1, height H1, and contacts the cap 716, the seals 714, the IC 708, and the substrate 702. Accordingly, the shape of the left side (contact side) surface of the encapsulant 712 conforms to the shape of the cap 716, the seals 714, the IC 708, and the substrate 702. The shape of the right side (non-contact side) surface of the encapsulant 712 is a slope that extends from the cap 716 to the substrate 702. As shown, the angle of the slope of the right side surface of the encapsulant 712 may vary. Also, some of the encapsulant 712 fills the bond pad well 720 of the substrate 702.

In the example of FIG. 7, the IC 708, the seals 714, and the cap 716 form a sealed chamber 718. Also, the bond pads 704 of the substrate 702 are in the bond pad well 720, which is offset from (below) the primary surface 703 of the substrate 702. In the example of FIG. 7, the IC 708 is attached to the primary surface 703 of the substrate 702 by an adhesive material 726. In the example of FIG. 7, the encapsulant 712 has a width W1 and a height H1, where H1 is relative to the primary surface 703 of the substrate 702.

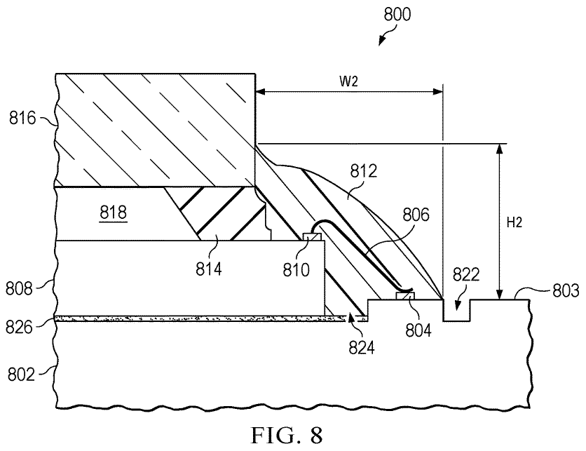

In the example of FIG. 8, the packaged circuit components in the cross-sectional view 800 include: a substrate 802 with primary surface 803, a cavity 824, and an encapsulant control well 822; an IC 808; seals 814; a cap 816 (e.g., a transparent material, such as glass, or a non-transparent material, such as a semiconductor material); bond pads 810 of the IC 808; bond pads 804 of the substrate 802; bond wires 806; and an encapsulant 812. In the example of FIG. 8, the encapsulant 812 has width W2, height H2, and contacts the cap 816, the seals 814, the IC 808, and the substrate 802. Accordingly, the shape of the left side (contact side) surface of the encapsulant 812 conforms to the shape of the cap 816, the seals 814, the IC 808, and the substrate 802. The shape of the right side (non-contact side) surface of the encapsulant 812 is a slope that extends from the cap 816 to the substrate 802. As shown, the angle of the slope of the right side surface of the encapsulant 812 may vary. Also, some of the encapsulant 812 fills the cavity 824 of the substrate 802.

In the example of FIG. 8, the IC 808, the seals 814, and the cap 816 form a sealed chamber 818. Also, the bond pads 804 of the substrate 802 are on the primary surface 803 of the substrate 802. In the example of FIG. 8, the IC 808 is attached to the substrate 802 in the cavity 824 by an adhesive material 826. Also, the encapsulant 812 has a width W2 and a height H2, where H2 is relative to the primary surface 803 of the substrate 802. Relative to the encapsulant 712 of FIG. 7, the encapsulant 812 of FIG. 8 has a reduced height (i.e., H2 is less than H1) due to the IC 808 being positioned in a cavity (e.g., the cavity 824) rather than a primary surface (e.g., the primary surface 703) of a substrate. The reduced height, the reduced dimensions, the reduced contact surface with other components, and/or the reduced slope of the encapsulant 812 relative to the encapsulant 712 is one way to reduce package strain caused by different materials having different CTEs and the package being subject to different temperatures.

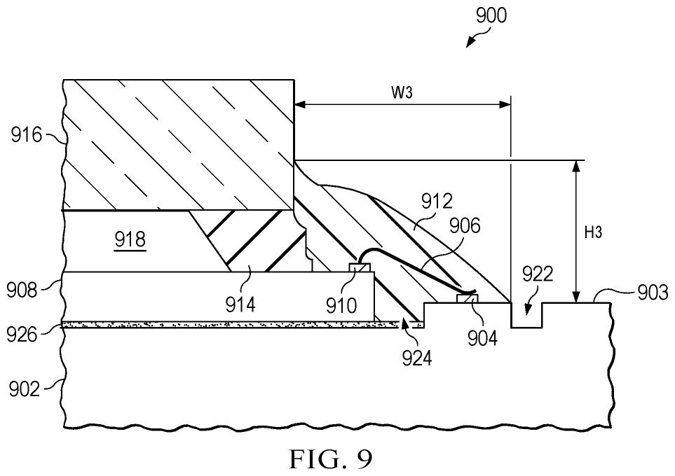

In the example of FIG. 9, the packaged circuit components in the cross-sectional view 900 include: a substrate 902 with primary surface 903, a cavity 924, and an encapsulant control well 922; an IC 908; seals 914; a cap 916 (e.g., a transparent material, such as glass, or a non-transparent material, such as a semiconductor material); bond pads 910 of the IC 908; bond pads 904 of the substrate 902; bond wires 906; and an encapsulant 912. In the example of FIG. 9, the encapsulant 912 has width W3, height H3, and contacts the cap 916, the seals 914, the IC 908, and the substrate 902. Accordingly, the shape of the left side (contact side) surface of the encapsulant 912 conforms to the shape of the cap 916, the seals 914, the IC 908, and the substrate 902. The shape of the right side (non-contact side) surface of the encapsulant 912 is a slope that extends from the cap 916 to the substrate 902. As shown, the angle of the slope of the right side surface of the encapsulant 912 may vary. Also, some of the encapsulant 912 fills the cavity 924 of the substrate 902.

In the example of FIG. 9, the IC 908, the seals 914, and the cap 916 form a sealed chamber 918. Also, the bond pads 904 of the substrate 902 are on the primary surface 903 of the substrate 902. In the example of FIG. 9, the IC 908 is attached to the substrate 902 in the cavity 924 by an adhesive material 926. Also, the encapsulant 912 has a width W3 and a height H3, where H3 is relative to the primary surface 903 of the substrate 902. Relative to the encapsulant 812 of FIG. 8, the encapsulant 912 of FIG. 9 has a reduced height (i.e., H3 is less than H2) due to the IC 908 having a reduced height relative to the IC 808. The reduced height, the reduced dimensions, the reduced contact surface with other components, and/or the reduced slope of the encapsulant 912 relative to the encapsulants 712 and 812 is one way to reduce package strain caused by different materials having different CTEs and the package being subject to different temperatures.

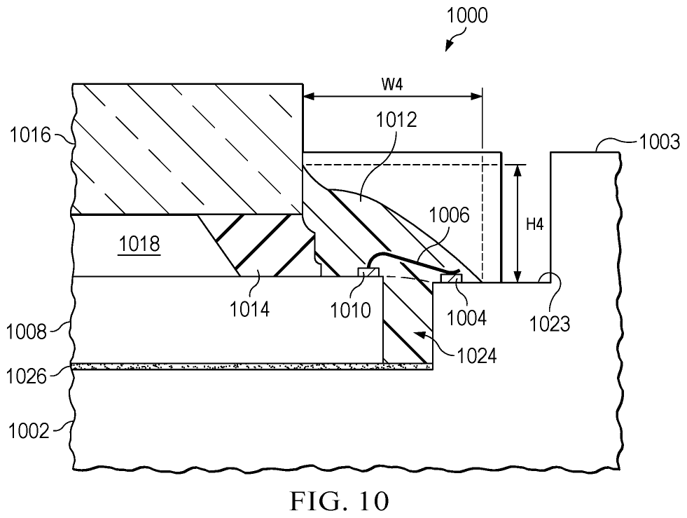

In the example of FIG. 10, the packaged circuit components in the cross-sectional view 1000 include: a substrate 1002 with primary surface 1003, a secondary surface 1023, and a cavity 1024; an IC 1008; seals 1014; a cap 1016 (e.g., a transparent material, such as glass, or a non-transparent material, such as a semiconductor material); bond pads 1010 of the IC 1008; bond pads 1004 of the substrate 1002; bond wires 1006; and an encapsulant 1012. In the example of FIG. 10, the encapsulant 1012 has width W4, height H4, and contacts the cap 1016, the seals 1014, the IC 1008, and the substrate 1002. Accordingly, the shape of the left side (contact side) surface of the encapsulant 1012 conforms to the shape of the cap 1016, the seals 1014, the IC 1008, and the substrate 1002. The shape of the right side (non-contact side) surface of the encapsulant 1012 is a slope that extends from the cap 1016 to the substrate 1002. As shown, the angle of the slope of the right side surface of the encapsulant 1012 may vary. Also, some of the encapsulant 1012 fills the cavity 1024 of the substrate 1002.

In the example of FIG. 10, the IC 1008, the seals 1014, and the cap 1016 form a sealed chamber 1018. Also, the bond pads 1004 of the substrate 1002 are on the secondary surface 1023 of the substrate 1002. In the example of FIG. 10, the IC 1008 is attached to the substrate 1002 in the cavity 1024 by an adhesive material 1026. Also, the encapsulant 1012 has a width W4 and a height H4, where H4 is relative to the secondary surface 1023 of the substrate 1002. Relative to the encapsulant 912 of FIG. 9, the encapsulant 1012 of FIG. 10 has a reduced height (i.e., H4 is less than H3) due to the cavity 1024 being deeper than the cavity 924 in FIG. 9. Also, the encapsulant 1012 of FIG. 10 has a reduced width (i.e., W4 is less than W1 in FIG. 7, W2 in FIG. 8, and W3 in FIG. 9) The reduced height and/or width, the reduced dimensions, the reduced contact surface with other components, and/or the reduced slope of the encapsulant 1012 relative to the encapsulants 712, 812, and 912 is one way to reduce package strain caused by different materials having different CTEs and the package being subject to different temperatures.

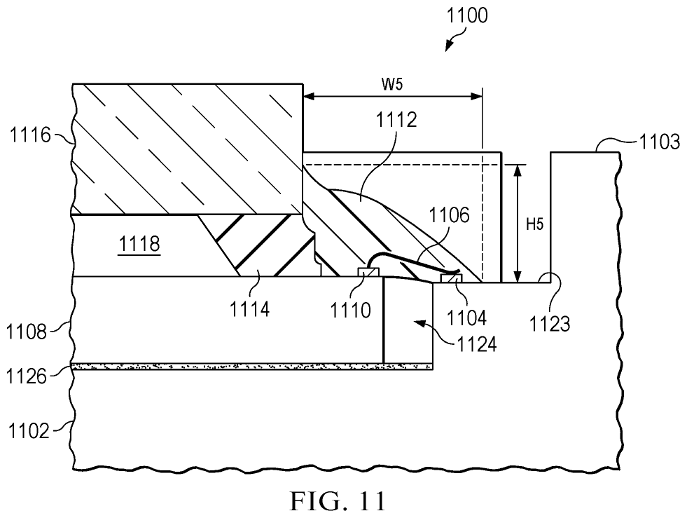

In the example of FIG. 11, the packaged circuit components in the cross-sectional view 1100 include: a substrate 1102 with primary surface 1103, a secondary surface 1123, and a cavity 1124; an IC 1108; seals 1114; a cap 1116 (e.g., a transparent material, such as glass, or a non-transparent material, such as a semiconductor material); bond pads 1110 of the IC 1108; bond pads 1104 of the substrate 1102; bond wires 1106; and an encapsulant 1112. In the example of FIG. 11, the encapsulant 1112 has width W5, height H5, and contacts the cap 1116, the seals 1114, the IC 1108, and the substrate 1102. Accordingly, the shape of the left side (contact side) surface of the encapsulant 1112 conforms to the shape of the cap 1116, the seals 1114, the IC 1108, and the substrate 1102. The shape of the right side (non-contact side) surface of the encapsulant 1112 is a slope that extends from the cap 1116 to the substrate 1102. As shown, the angle of the slope of the right side surface of the encapsulant 1112 may vary. Also, the encapsulant 1112 does not fill the cavity 1124 of the substrate 1102.

In the example of FIG. 11, the IC 1108, the seals 1114, and the cap 1116 form a sealed chamber 1118. Also, the bond pads 1104 of the substrate 1102 are on the secondary surface 1123 of the substrate 1102. In the example of FIG. 11, the IC 1108 is attached to the substrate 1102 in the cavity 1124 by an adhesive material 1126. Also, the encapsulant 1112 has a width W5 and a height H5, where H5 is relative to the secondary surface 1123 of the substrate 1102. Relative to the encapsulant 1012 of FIG. 10, the dimensions of the encapsulant 1112 of FIG. 11 are about the same (i.e., H5 is about the same as H4, and W5 is about the same as W4). However, in contrast to the example of FIG. 10, where the encapsulant 1012 fills the cavity 1024, the encapsulant 1112 does not fill the cavity 1124 in FIG. 11. Preventing encapsulant from filling a cavity as in FIG. 11 is one way to reduce package strain caused by different materials having different CTEs and the package being subject to different temperatures.

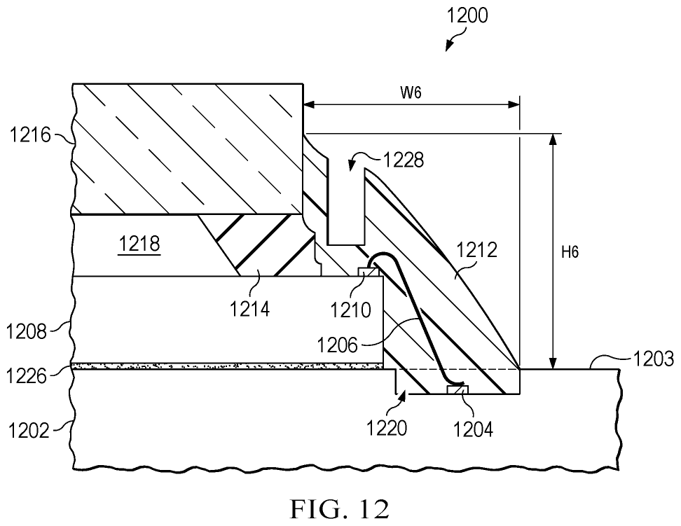

In the example of FIG. 12, the packaged circuit components in the cross-sectional view 1200 include: a substrate 1202 with a primary surface 1203, and a bond pad well 1220; an IC 1208; seals 1214; a cap 1216 (e.g., a transparent material, such as glass, or a non-transparent material, such as a semiconductor material); bond pads 1210 of the IC 1208; bond pads 1204 of the substrate 1202; bond wires 1206; and an encapsulant 1212. In the example of FIG. 12, the encapsulant 1212 has width W6, height H6, and contacts the cap 1216, the seals 1214, the IC 1208, and the substrate 1202. Accordingly, the shape of the left side (contact side) surface of the encapsulant 1212 conforms to the shape of the cap 1216, the seals 1214, the IC 1208, and the substrate 1202. Also, some of the encapsulant 1212 fills the cavity 1224 of the substrate 1202. The shape of the right side (non-contact side) surface of the encapsulant 1212 is a notched slope that extends from the cap 1216 to the substrate 1202. In different examples, the size (e.g., the width and/or the height) and/or the number of notches (e.g., the notch 1228) in the encapsulant 1212 may vary.

In the example of FIG. 12, the IC 1208, the seals 1214, and the cap 1216 form a sealed chamber 1218. Also, the bond pads 1204 of the substrate 1202 are in the bond pad well 1220, which is offset from (below) the primary surface 1203 of the substrate 1202. In the example of FIG. 12, the IC 1208 is attached to the primary surface 1203 of the substrate 1202 by an adhesive material 1226. In the example of FIG. 12, the encapsulant 1212 has a width W6 and a height H6, where H6 is approximately the same as H1. However, in contrast to the encapsulant 712 in FIG. 7, the encapsulant 1212 in FIG. 12 includes the notch 1228. Adding one or more notches to an encapsulant as in FIG. 12 is one way to reduce package strain caused by different materials having different CTEs and the package being subject to different temperatures.

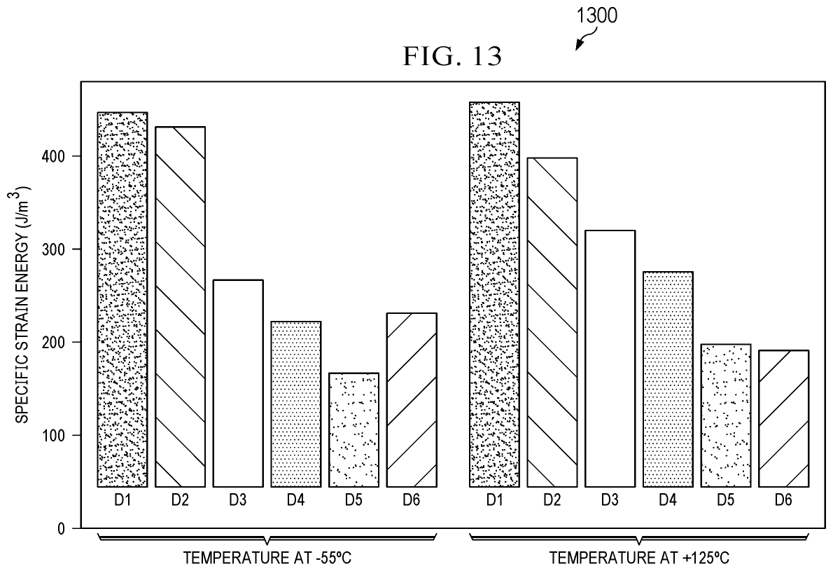

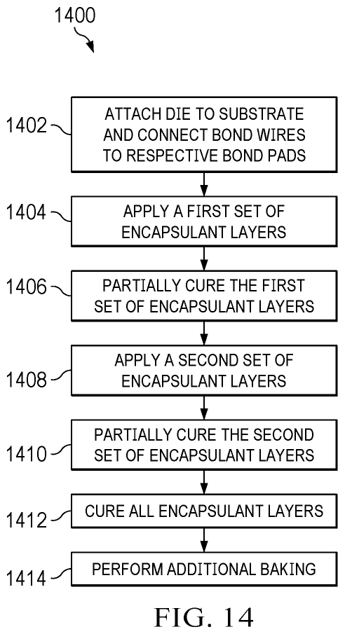

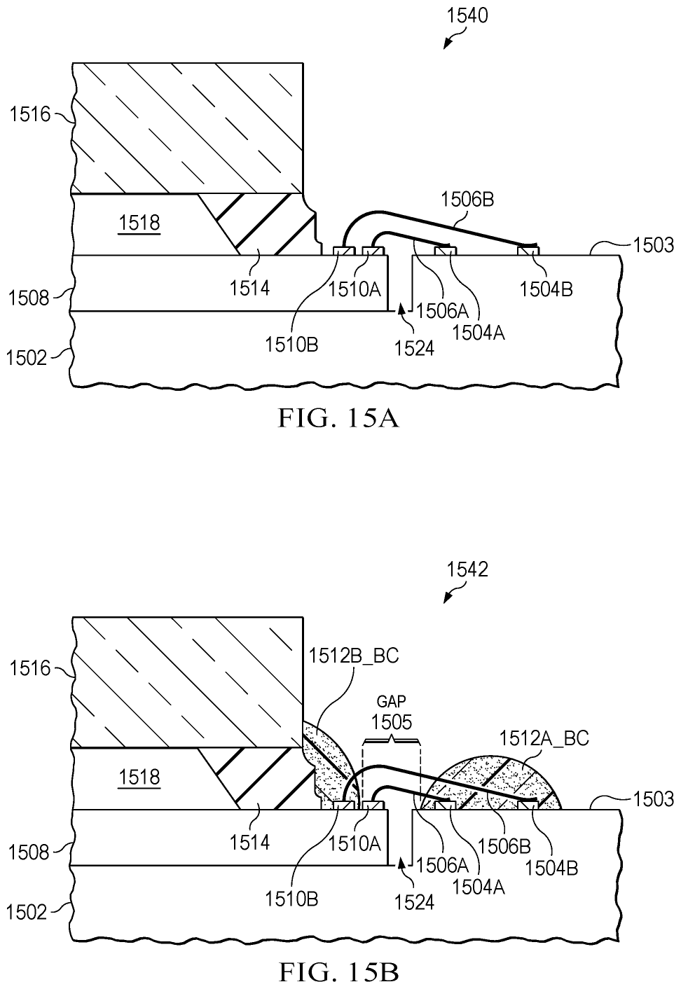

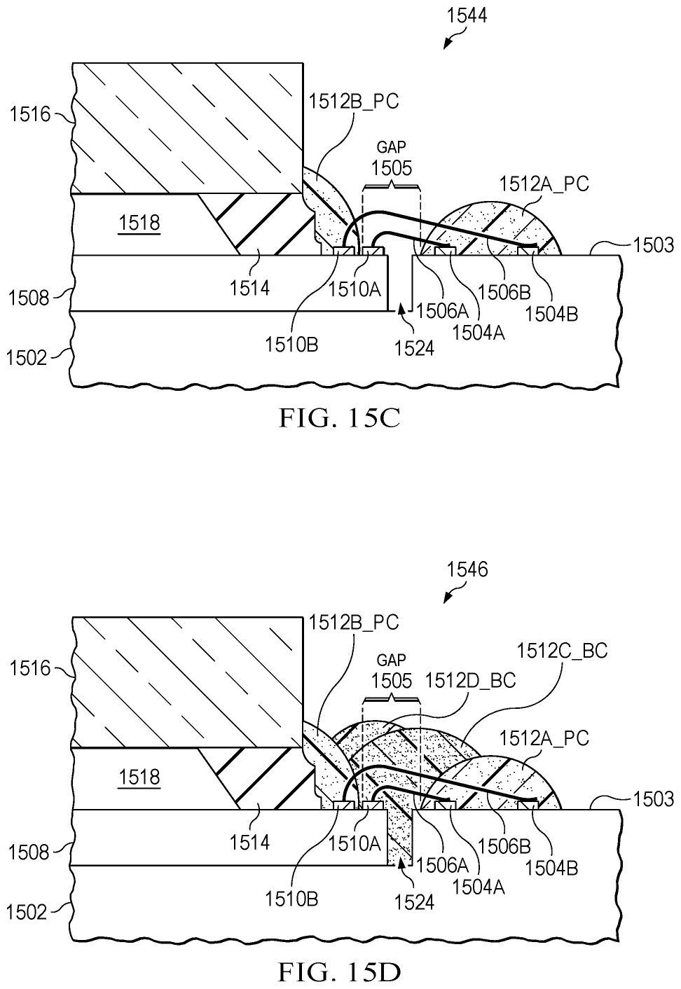

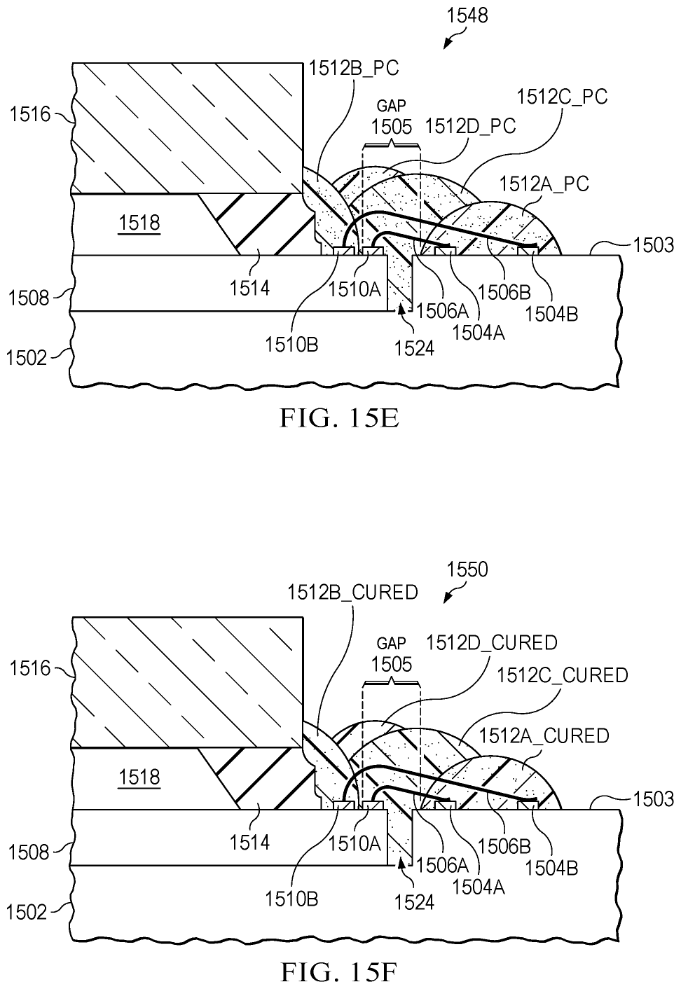

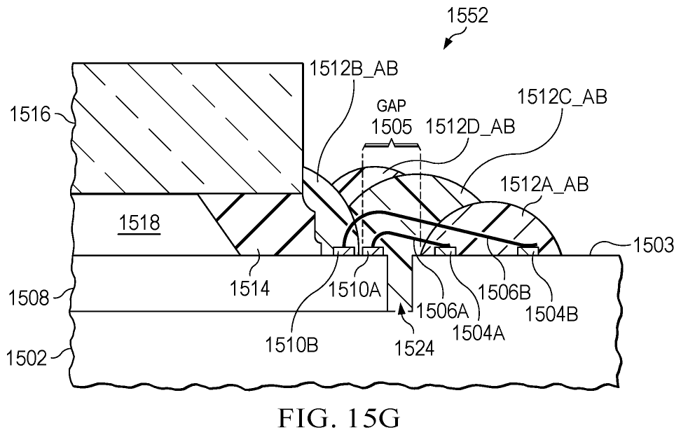

In the examples of FIGS. 7 to 12, the width W1 of the encapsulant 712, the width W2 of the encapsulant 812, the width W3 of the encapsulant 912, and the width W6 of the encapsulant 1012 are about the same, while the width W4 of the encapsulant 1012 and the width W5 of the encapsulant 1112 are less than W1, W2, W3, and W6. Also, the height H1 of the encapsulant 712 and the height H6 of the encapsulant 1212 are about the same, while the height H2 of the encapsulant 812 is less than H1 and H6, the height H3 of the encapsulant 912 is less than H2, the height H4 of the encapsulant 1012 is less than H3, and the height H5 of the encapsulant 1112 is about the same as H4. Reducing encapsulant volume can reduce the amount of strain, during testing or subsequent use, due to different temperatures and different CTEs of the components. In the described examples, reducing the volume of an encapsulant (e.g., encapsulants 812, 912, 1012 have reduced volumes relative to encapsulant 712 herein), selective positioning of an encapsulant (e.g., encapsulant 1112 does not fill the cavity 1124 or encapsulant 912 does not extend beyond the encapsulant control well 922), use of notches in an encapsulant (e.g., see notch 1228 in FIG. 12), and/or strategic curing of encapsulant layers (as in the method of FIG. 14 or related examples in FIGS. 15A to 15G) may be used to reduce strain of during testing or subsequent use, due to different temperatures and different CTEs of the components.

In some examples, any of the features described in FIGS. 4 to 12 may be used individually or may be used in combination. For example, each of the features described in FIGS. 4 to 12 may be applied to the example packages in FIGS. 2A, 2B, 3A, and 3B. In different examples, encapsulant layer control (e.g., encapsulant 1112 does not fill the cavity 1124 or encapsulant 912 does not extend beyond the encapsulant control well 922) may be used to reduce package strain due to temperature and CTE variance (compared to no encapsulant layer control). As another option, encapsulant volume reduction (e.g., encapsulants 812, 912, 1012 have reduced volumes relative to encapsulant 712 herein) may be used to reduce package strain due to temperature and CTE variance (e.g., a 20-45% encapsulant volume reduction may be used relative to previous encapsulants). Reducing the volume of an encapsulant as described herein reduces the amount of contact between materials with different CTEs and reduces the amount of thermal contraction of an encapsulant when temperature decreases and/or reduces the amount of thermal expansion of an encapsulant when temperature temperatures. As another option, the amount of die attached coverage may be increased to reduce package strain due to temperature and CTE variance (e.g., increasing die attached coverage from less than 80% to 100%). The die attached coverage refers to the coverage of the adhesive material 726, 826, 926, 1026, 1126, and 1226 between an IC and a substrate. Although less than 100% die attached coverage (e.g., 80% or less) may be acceptable for some applications, increasing the die attached coverage is one way to reduce strain due to package materials having different CTEs and the package being subject to different temperatures. As another option, reduction of the dimensions of an encapsulant in a particular direction (e.g., the W direction, the L direction, and/or the H direction described herein) may be used to reduce package strain due to temperature and CTE variance. For example, reducing height of an encapsulant (e.g., H4 in FIG. 10 is less than H1 in FIG. 7, H2 in FIG. 8, and H3 in FIG. 9) is one way to reduce strain due to package materials having different CTEs and the package being subject to different temperatures. Reducing width of an encapsulant (e.g., W4 in FIG. 10 is less than W1 in FIG. 7, W2 in FIG. 8, and W3 in FIG. 9) may provide similar benefits.

As another option, changing the position of bond pads, bond wires, and respective encapsulants for a particular package may reduce package strain due to temperature and CTE variance (e.g., use of encapsulant on 2, 3, or 4 sides of an IC). For example, adding bond pads to different sides of an IC and substrate as in FIGS. 2A, 2B, 3A, and 3B may help reduce the volume of encapsulant used on a single side and thus may reduce strain on that particular side. Additional dispersion of bonds pads and bond wires to 3 or 4 sides of an IC may further reduce the volume of encapsulant used for each side and provide the benefit of reduced strain due to package materials having different CTEs and the package being subject to different temperatures. In different examples, the encapsulant options described herein may be applied to ball and/or stitch bond package configurations. As another option, encapsulant control wells (e.g., the encapsulant control well 422 in FIG. 4, the encapsulant control well 722 in FIG. 7, the encapsulant control well 822 in FIG. 8, or the encapsulant control well 922 in FIG. 9) may reduce package strain due to temperature and CTE variance. As another option, substrates with bond pad wells (e.g., bond pad well 420 in FIG. 4, bond pad well 720 in FIG. 7, or bond pad well 1220 in FIG. 12), bond pad shelves (e.g., the bond pad shelf 520 in FIG. 5, the bond pad shelf formed by the secondary surface 1023 in FIG. 10, or the bond pad shelf formed by the secondary surface 1123 in FIG. 11) and/or cavities (e.g., the cavity 424, 524, 624, 824, 924, 1024, and 1124 in FIGS. 4 to 6, and 8 to 11) may be used to control encapsulant dimensions and reduce package strain due to temperature and CTE variance. As another option, substrates with encapsulant control wells (e.g., the encapsulant control well 422 in FIG. 4, encapsulant control well 722 in FIG. 7, encapsulant control well 822 in FIG. 8, or encapsulant control well 922 in FIG. 9) and/or other dummy features may reduce package strain due to temperature and CTE variance.

FIG. 13 is a graph 1300 of specific strain energy (J/m³) for different packaged circuit designs D1, D2, D3, D4, D5, D6 and temperatures. The example temperatures in FIG. 13 are −55° C. and +125° C. The design D1 in the graph 1300 corresponds to the example of FIG. 7. The design D2 in the graph 1300 corresponds to the example of FIG. 8. The design D3 in the graph 1300 corresponds to the example of FIG. 9. The design D4 in the graph 1300 corresponds to the example of FIG. 10. The design D5 in the graph 1300 corresponds to the example of FIG. 11. The design D6 in the graph 1300 corresponds to the example of FIG. 12. At −55° C., the designs D1 and D2 have the highest specific strain energy and the design D5 has the least specific strain energy. The designs D3, D4, D5, and D6 may be considered to be acceptable (e.g., below a target specific strain energy) for the −55° C. scenario. At +125° C., the designs D1 and D2 have the highest specific strain energy and the design D6 has the least specific strain energy. The designs D5 and D6 may be considered to be acceptable (e.g., below a target specific strain energy) for the +125° C. scenario. The combined results of both temperatures in graph 1300 indicate that designs D5 and D6 have reduced strain compared to the designs D1, D2, D3, and D4. Depending on a target application and temperature range, different package designs and encapsulant processes may be used, individually or in combination, to achieve a target specific strain energy.

FIG. 14 is a method 1400 in accordance with various examples. FIGS. 15A to 15G are cross-sectional views 1540, 1542, 1544, 1546, 1548, 1550, and 1552 related to the method of FIG. 14 in accordance with various examples. The method 1400 may be used with any of the substrate and IC configurations described herein. Such substrate and IC configurations may vary with regard to use of a cap and related seals, a substrate cavity, a substrate bond pad well, a substrate bond pad shelf, a substrate encapsulant control well, the numbers of sides of the IC that have bond pads (e.g., 1 side up to 4 sides), the encapsulant layer volume, the number of encapsulant layers, the type of bond pad or ball, the partial cure time and temperature, the cure time and temperature, the bake time and temperature, and/or other packaging options, dimensions, and parameters. As shown, the method 1400 includes attaching an IC die to a substrate and connecting bond wires to respective bond pads at block 1402. At block 1404, a first set of encapsulant layers are applied. In some examples, the first set of encapsulant get layers includes 2 gel layers spaced away from each other by a gap (e.g., the gap 405 in FIG. 4, the gap 505 in FIG. 5, the gap 605 in FIG. 6, or the gap 1505 in FIGS. 15B to 15G). In some examples, the gap may have a width of 0.1 mm to 3 mm.

At block 1406, the first set of encapsulant layers are partially cured. In some examples, the first set of encapsulant layers are partially cured at block 1406 for about 7 minutes (+/−5%) at about 110° C. (+/−10%). At block 1408, a second set of encapsulant layers are applied. In some examples, the second set of encapsulant get layers includes 1 or 2 gel layers that at least partially cover any gaps remaining between encapsulant layers of the first set of encapsulant layers. At block 1410, the second set of encapsulant layers are partially cured. In some examples, the second set of encapsulant layers are partially cured at block 1410 for about 10 minutes (+/−5%) at about 110° C. (+/−10%). At block 1412, all encapsulant layers are cured. In some examples, all encapsulant layers are cured at block 1412 for at least 90 minutes at about 118° C. (+/−5%). At block 1414, additional baking is performed. In some examples, additional baking for at least 10 hours at about 153° C. (+/−5%) is performed at block 1414.

The cross-sectional view 1540 of FIG. 15A relates to block 1402 of FIG. 14 and shows a cross-sectional view 1540 of packaged circuit components before encapsulant layers are applied. In the example of FIG. 15A, the packaged circuit components in the cross-sectional view 1540 include: a substrate 1502 with primary surface 1503 and a cavity 1524 relative to the primary surface 1503; an IC 1508; seals 1514; a cap 1516 (e.g., a transparent material, such as glass, or a non-transparent material, such as a semiconductor material); bond pads 1510A of the IC 1508; bond pads 1510B of the IC 1508; bond pads 1504A of the substrate 1502; bond pads 1504B of the substrate 1502; bond wires 1506A; and bond wires 1506B.

In the example of FIG. 15A, the IC 1508, the seals 1514, and the cap 1516 form a sealed chamber 1518. Also, the bond pads 1504A and the bond pads 1504B are on the primary surface 1503 of the substrate 1502. In the example of FIG. 15, the IC 1508 is attached to the substrate 1502 within the cavity 1524 such that the top of the IC 1508 is aligned with the primary surface 1503 of the substrate 1502. In other examples, the top of the IC 1508 may be offset (above or below) the primary surface 1503 of the substrate 1502. In other examples, the substrate 1502 may include other features such as bond pad wells, bond pad shelves, and/or encapsulant control wells.

The cross-sectional view 1542 of FIG. 15B shows the application of two encapsulant layers 1512A_BC and 1512B_BC spaced away from each other by a gap 1505 as example operations of block 1404. In the cross-sectional view 1542 of FIG. 15B, the designation BC refers to “before curing”. The encapsulant layers 1512A_BC and 1512B_BC are examples of the first and second encapsulant layers 412A and 412B before curing in FIG. 4, the first and second encapsulant layers 512A and 512B before curing in FIG. 5, or the first and second encapsulant layers 612A and 612B before curing in FIG. 6.

In different examples, the size of the gap 1505 may vary depending on: the spacing between bond pads of the IC 1508 (e.g., the bond pads 1510A and/or the bond pads 1510B) and bond pads of the substrate 1502 (e.g., the bonds pads 1504A and/or the bond pads 1504B); the position of the seals 1514 relative to bonds pads of the IC 1508 (e.g., the bond pads 1510A and/or the bond pads 1510B), the outer edge of the IC 1508, or the dimensions of the cavity 1524; the position of the cap 1516 relative to the bond pads of the IC 1508 (e.g., the bond pads 1510A and/or the bond pads 1510B), the outer edge of the IC 1508, or the dimensions of the cavity 1524. In some examples, the size of the gap 1505 is determined, at least in part, by the volume of encapsulant dispensed for each encapsulant layer during encapsulation operations. The volume of encapsulant dispensed for each encapsulant layer may vary, for example, based on available dispensing technology, cost considerations, and strain reduction targets. In different examples, the number, the size, and the position of encapsulant layers may vary.

The cross-sectional view 1546 of FIG. 15C shows partially cured encapsulant layers 402A_PC and 402B_PC resulting from example operations of block 1406. In the cross-sectional view 1544 of FIG. 15C, the designation PC refers to “partially cured”. The cross-sectional view 1546 of FIG. 15D shows the application of two encapsulant layers 1512C_BC and 1512D_BC covering the gap between the encapsulant layers 1512A_PC and 1512B_PC as example operations of block 1408. In the cross-sectional view 1546 of FIG. 15D, the designation BC refers to “before curing” and the designation PC refers to “partially cured”. The cross-sectional view 1548 of FIG. 15E shows partially cured encapsulant layers 1512C_PC and 1512D_PC resulting from example operations of block 1410. The result of block 1410 is that the encapsulant layers 1512A_PC, 1512B_PC, 1512C_PC, and 1512D_PC are partially cured. The cross-sectional view 1550 of FIG. 15F shows cured encapsulant layers 1512A_CURED, 1512B_CURED, 1512C_CURED, and 1512D_CURED, representing the transition of the first and second encapsulant layers from a before curing state at blocks 1404 and 1408, to a partially cured state at blocks 1406 and 1410, to a cured state at block 1412. The cross-sectional view 1552 of FIG. 15G shows additionally baked encapsulant layers 1512A_AB, 1512B_AB, 1512C_AB, and 1512D_AB. In the cross-sectional view 1552 of FIG. 15G, the designation AB (e.g., 1512A_AB, 1512B_AB, etc.) refers to “additionally baked”.

In some examples, block 1404 includes applying a first encapsulant layer, the first encapsulant layer contacting the substrate and spaced away from the IC. In some examples, block 1406 includes partially curing the first encapsulant layer. In some examples, block 1404 includes applying a second encapsulant layer, the second encapsulant layer contacting the IC and spaced away from the substrate, and the second encapsulant layer separated from the first encapsulant layer by a gap. In some examples, block 1406 includes partially curing the second encapsulant layer. In some examples, block 1408 includes applying a third encapsulant layer, the third encapsulant layer contacting at least one of the first encapsulant layer and the second encapsulant layer, the third encapsulant layer at least partially covering the gap. In some examples, block 1410 includes partially curing the third encapsulant layer. In some examples, block 1412 includes curing the first encapsulant layer, the second encapsulant layer, and the third encapsulant layer.

In some examples, partially curing the first encapsulant layer at block 1406 includes performing a bake at a temperature below 150° Celsius for less than 50 minutes, and partially curing the second encapsulant layer at block 1406 includes performing a bake at a temperature below 150° Celsius for less than 50 minutes. In some examples, curing the first encapsulant layer, the second encapsulant layer, and the third encapsulant layer at block 1412 includes performing a bake at a temperature above 120° Celsius for at least 60 minutes.

In some examples, the method 1400 includes applying a cap over the IC before applying the second encapsulant layer, the second encapsulant layer contacting the IC and the cap. In some examples, the method 1400 includes forming a cavity in the substrate; and positioning the IC in a cavity of the substrate for attaching the IC to the substrate. In some examples, the method 1400 includes forming a bond pad well in the substrate, the bond pad well including bond pads, wherein the first encapsulant layer covers the bond pads. In some examples, the method 1400 includes forming a set of bond pads in the substrate; and forming an encapsulant control well separate from the set of bond pads, wherein applying the first encapsulant layer includes positionally limiting the first encapsulant layer based on the encapsulant control well.

In some examples, an apparatus includes: a substrate having a first set of bond pads; an IC having a second set of bond pads; bond wires between bond pads of the first set of bond pads and respective bond pads of the second set of bond pads; a first encapsulant layer in contact with the substrate and spaced away from the IC; a second encapsulant layer in contact with the IC and spaced away from the substrate, the second encapsulant layer separated from the first encapsulant layer by a gap; and a third encapsulant layer in contact with at least one of the first encapsulant layer and the second encapsulant layer, the third encapsulant layer at least partially covering the gap. In some examples, the substrate includes a cavity, and the IC is positioned in the cavity. In some examples, the substrate includes a bond pad shelf offset from the cavity, the bond pad shelf includes the first set of bond pads, and the first encapsulant layer covers the first set of bond pads. In some examples, the substrate includes a bond pad well having the first set of bond pads, and the first encapsulant layer covers the first set of bond pads. In some examples, the substrate includes an encapsulant control well separate from the first set of bond pads, and an outer edge of the first encapsulant layer is in the encapsulant control well.

In some examples, the IC comprises a spatial light modulator, the substrate is a ceramic material, the apparatus further comprises a cap over the spatial light modulator, the cap forms a sealed cavity over the spatial light modulator, and the second encapsulant layer is in contact with the cap. In some examples, the first encapsulant layer, the second encapsulant layer, and the third encapsulant layer form a combined encapsulant over the bond wires, the combined encapsulant having a width between 0.5 mm to 4 mm and having a height between 0.5 mm to 5 mm. In some examples, the first encapsulant layer, the second encapsulant layer, and the third encapsulant layer are made from epoxy gel having a CTE below 25.

In some examples, a vehicle includes: an ECU; and projection circuitry coupled to the ECU. In such examples, the projection circuitry includes an SLM. The SLM includes: a substrate having a first set of bond pads; an IC having a second set of bond pads; bond wires between bond pads of the first set of bond pads and respective bond pads of the second set of bond pads; a first encapsulant layer in contact with the substrate and spaced away from the IC; a second encapsulant layer in contact with the IC and spaced away from the substrate, the second encapsulant layer separated from the first encapsulant layer by a gap; and a third encapsulant layer in contact with at least one of the first encapsulant layer and the second encapsulant layer, the third encapsulant layer at least partially covering the gap. In some examples, the projection circuitry provides a projection selected from the list consisting of: a smart headlight projection; an HUD projection; a ground projection; an internal display projection; a window display projection; and a LIDAR projection.

In some examples, the projection circuitry is first projection circuitry, the SLM is a first SLM, the substrate is a first substrate, the IC is a first IC, the bond wires are first bond wires, the gap is a first gap, and the vehicle includes second projection circuitry coupled to the ECU. In such examples, the second projection circuitry includes a second SLM. The second SLM includes: a second substrate having a third set of bond pads; a second IC having a fourth set of bond pads; second bond wires between bond pads of the third set of bond pads and respective bond pads of the fourth set of bond pads; a fourth encapsulant layer in contact with the second substrate and spaced away from the second IC; a fifth encapsulant layer in contact with the second IC and spaced away from the second substrate, the fifth encapsulant layer separated from the fourth encapsulant layer by a second gap; and a sixth encapsulant layer in contact with at least one of the fourth encapsulant layer and the fifth encapsulant layer, the sixth encapsulant layer at least partially covering the second gap.

In some examples, the substrate includes a cavity, and the IC is positioned in the cavity. In some examples, the substrate includes at least one of: a bond pad shelf offset from the cavity, the bond pad shelf includes the first set of bond pads, and the first encapsulant layer covers the first set of bond pads; a bond pad well having the first set of bond pads; and an encapsulant control well separate from the first set of bond pads.

In some examples, a method of packaging a MEMS device includes: obtaining a substrate having an IC; applying a first encapsulant layer, the first encapsulant layer contacting the substrate and spaced away from the IC; applying a second encapsulant layer, the second encapsulant layer contacting the IC and spaced away from the substrate, and the second encapsulant layer separated from the first encapsulant layer by a gap; partially curing the first encapsulant layer and the second encapsulant layer; applying a third encapsulant layer after partially curing the first encapsulant layer and the second encapsulant layer, the third encapsulant layer contacting at least one of the first encapsulant layer and the second encapsulant layer, the third encapsulant layer at least partially covering the gap; and curing the first encapsulant layer, the second encapsulant layer, and the third encapsulant layer.

In some examples, partially curing the first and second encapsulant layers includes performing a bake at a temperature below 150° Celsius for less than 50 minutes. In some examples, curing the first encapsulant layer, the second encapsulant layer, and the third encapsulant layer includes performing a bake at a temperature above 120° Celsius for at least 60 minutes.

In some examples, the method of packaging a MEMS device includes applying a cap over the IC before applying the second encapsulant layer, the second encapsulant layer contacting the IC and the cap. In some examples, the method of packaging a MEMS device includes attaching the IC to the substrate; and connecting bond wires between bond pads of the IC and bond pads of the substrate. In some examples, the method of packaging a MEMS device includes forming a bond pad well in the substrate, the bond pad well including bond pads, wherein the first encapsulant layer covers the bond pads. In some examples, the method of packaging a MEMS device includes: forming a set of bond pads in the substrate; and forming an encapsulant control well separate from the set of bond pads, wherein applying the first encapsulant layer includes positionally limiting the first encapsulant layer based on the encapsulant control well.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. An apparatus comprising:
a substrate having a first set of bond pads;
an integrated circuit (IC) having a second set of bond pads;
bond wires between bond pads of the first set of bond pads and respective bond pads of the second set of bond pads;
a first encapsulant layer in contact with the substrate and spaced away from the IC;
a second encapsulant layer in contact with the IC and spaced away from the substrate, the second encapsulant layer separated from the first encapsulant layer by a gap; and
a third encapsulant layer in contact with at least one of the first encapsulant layer and the second encapsulant layer, the third encapsulant layer at least partially covering the gap.

2. The apparatus of claim 1, wherein the substrate includes a cavity, and the IC is positioned in the cavity.

3. The apparatus of claim 2, wherein the substrate includes a bond pad shelf offset from the cavity, the bond pad shelf includes the first set of bond pads, and the first encapsulant layer covers the first set of bond pads.

4. The apparatus of claim 1, wherein the substrate includes a bond pad well having the first set of bond pads, and the first encapsulant layer covers the first set of bond pads.

5. The apparatus of claim 1, wherein the substrate includes an encapsulant control well separate from the first set of bond pads, and an outer edge of the first encapsulant layer is in the encapsulant control well.

6. The apparatus of claim 1, wherein the IC comprises a spatial light modulator, the substrate is a ceramic material, the apparatus further comprises a cap over the spatial light modulator, the cap forms a sealed cavity over the spatial light modulator, and the second encapsulant layer is in contact with the cap.

7. The apparatus of claim 1, wherein the first encapsulant layer, the second encapsulant layer, and the third encapsulant layer form a combined encapsulant over the bond wires, the combined encapsulant having a width between 0.5 mm to 4 mm and having a height between 0.5 mm to 5 mm.

8. The apparatus of claim 1, wherein the first encapsulant layer, the second encapsulant layer, and the third encapsulant layer are made from epoxy gel having a coefficient of thermal expansion (CTE) below 25.

9. A vehicle comprising:
an electronic control unit (ECU); and
projection circuitry coupled to the ECU, the projection circuitry including a spatial light modulator (SLM), the SLM including:
a substrate having a first set of bond pads;
an integrated circuit (IC) having a second set of bond pads;
bond wires between bond pads of the first set of bond pads and respective bond pads of the second set of bond pads;
a first encapsulant layer in contact with the substrate and spaced away from the IC;
a second encapsulant layer in contact with the IC and spaced away from the substrate, the second encapsulant layer separated from the first encapsulant layer by a gap; and
a third encapsulant layer in contact with at least one of the first encapsulant layer and the second encapsulant layer, the third encapsulant layer at least partially covering the gap.

10. The vehicle of claim 9, wherein the projection circuitry provides a projection selected from the list consisting of:
a smart headlight projection;
a head-up display (HUD) projection;
a ground projection;
an internal display projection;
a window display projection; and
a light detection and ranging (LIDAR) projection.

11. The vehicle of claim 9, wherein the projection circuitry is first projection circuitry, the SLM is a first SLM, the substrate is a first substrate, the IC is a first IC, the bond wires are first bond wires, the gap is a first gap, and the vehicle further comprises second projection circuitry coupled to the ECU, the second projection circuitry including a second SLM that includes:
a second substrate having a third set of bond pads;
a second IC having a fourth set of bond pads;
second bond wires between bond pads of the third set of bond pads and respective bond pads of the fourth set of bond pads;
a fourth encapsulant layer in contact with the second substrate and spaced away from the second IC;
a fifth encapsulant layer in contact with the second IC and spaced away from the second substrate, the fifth encapsulant layer separated from the fourth encapsulant layer by a second gap; and
a sixth encapsulant layer in contact with at least one of the fourth encapsulant layer and the fifth encapsulant layer, the sixth encapsulant layer at least partially covering the second gap.

12. The vehicle of claim 9, wherein the substrate includes a cavity, and the IC is positioned in the cavity.

13. The vehicle of claim 12, wherein the substrate includes at least one of:
a bond pad shelf offset from the cavity, the bond pad shelf includes the first set of bond pads, and the first encapsulant layer covers the first set of bond pads;
a bond pad well having the first set of bond pads; and
an encapsulant control well separate from the first set of bond pads.

14. A method of packaging a microelectromechanical system (MEMS) device, the method comprising:
obtaining a substrate and an integrated circuit (IC);
applying a first encapsulant layer, the first encapsulant layer contacting the substrate and spaced away from the IC;
applying a second encapsulant layer, the second encapsulant layer contacting the IC and spaced away from the substrate, and the second encapsulant layer separated from the first encapsulant layer by a gap;
partially curing the first encapsulant layer and the second encapsulant layer;
applying a third encapsulant layer after partially curing the first encapsulant layer and the second encapsulant layer, the third encapsulant layer contacting at least one of the first encapsulant layer and the second encapsulant layer, the third encapsulant layer at least partially covering the gap; and
curing the first encapsulant layer, the second encapsulant layer, and the third encapsulant layer.

15. The method of claim 14, wherein partially curing the first and second encapsulant layers includes performing a bake at a temperature below 150° Celsius for less than 50 minutes.

16. The method of claim 14, wherein curing the first encapsulant layer, the second encapsulant layer, and the third encapsulant layer includes performing a bake at a temperature above 120° Celsius for at least 60 minutes.

17. The method of claim 14, further comprising applying a cap over the IC before applying the second encapsulant layer, the second encapsulant layer contacting the IC and the cap.

18. The method of claim 14, further comprising:
attaching the IC to the substrate; and
connecting bond wires between bond pads of the IC and bond pads of the substrate.

19. The method of claim 14, further comprising forming a bond pad well in the substrate, the bond pad well including bond pads, wherein the first encapsulant layer covers the bond pads.

20. The method of claim 14, further comprising:
forming a set of bond pads in the substrate; and
forming an encapsulant control well separate from the set of bond pads, wherein applying the first encapsulant layer includes positionally limiting the first encapsulant layer based on the encapsulant control well.
